(19) United States
(12) Patent Application Publication
(10) Pub. No.: US 2007/0072340 A1
(43) Pub. Date: Mar. 29, 2007

(54) Electronic Device with Inductor and Integrated Componentry

(76) Inventors: Christopher J. Sanzo, Providence, RI (US); Chuan Ni, West Warwick, RI (US); Michael G. Amaro, Naperville, IL (US)

Correspondence Address: Sam Tung;Texas Instruments Incorporated, M/S 3999, P.O. Box 655474, Dallas, TX, 75265, US

(21) Appl. No.: 11/554,908

(22) Filed: Oct. 31, 2006

Related U.S. Application Data
(63) Continuation of application No. 10/993,704, filed on Nov. 19, 2004.

(51) Int. Cl. H01L 21/00

(52) U.S. Cl. 438/106

(57) ABSTRACT

Semiconductor devices and methods for their assembly are described in which inductor elements and additional passive or active circuit components may be combined in novel configurations. An electronic device and associated methods provide an inductor element encapsulated within a dielectric package, the inductor package having a plurality of electrical contacts on at least one surface. One or more circuit components are affixed to the package surface and operably coupled to the electrical contacts. The circuit components have a total area not larger than the inductor package surface, providing a device with overall dimensions bounded by the area of the inductor package. A preferred method embodying the invention includes a step of selecting an inductor element configuration based on performance requirements. The inductor element is packaged in a dielectric package having electrical contacts disposed on one or more surface. Subsequently, one or more circuit components are operably coupled to the electrical contacts for operation in association with the inductor element.

### RELATED APPLICATION

This application is a continuation of a related application, Ser. No. 10/993,704 filed Nov. 19, 2004, incorporated herein by reference in its entirety, having common inventors and a common assignee.

### TECHNICAL FIELD

The invention relates to electronic semiconductor devices and manufacturing. More particularly, the invention relates to microelectronic semiconductor devices and methods and systems for implementing devices having at least one inductor element and at least one additional circuit component.

### BACKGROUND OF THE INVENTION

Microelectronic devices are being made increasingly smaller and densities are being made ever higher. In the case of point of load power supplies for example, exotic assembly and circuit techniques are sometimes required to reduce the size of power components. Meanwhile, the size of the control components is also getting smaller and smaller. Inductors are relatively large components, and therefore those skilled in the arts have frequently devoted attention to the reduction of inductor size.

An approach used in the arts is to mount the desired circuit components side-by-side. Using this approach, the smallest practical size inductor for a given application is mounted on a substrate, such as a printed circuit board (PCB). Adjacent to the inductor, additional circuit components, also of the smallest practical size, are attached to the PCB. Thus, the overall area of the system on the PCB includes the area occupied by the inductor, plus the area occupied by the additional components, plus any additional “wasted” area required in the layout due to electrical or mechanical constraints, such as gaps between components.

Trade-offs exist, however, in the design and implementation of smaller inductors. Physically smaller inductors, for example, tend to have higher resistance and tend to have reduced efficiency compared to their larger counterparts. Smaller inductors are also less able to withstand the application of high current levels. The desire for smaller devices may therefore be at odds with inductor performance requirements, resulting in sacrifices in performance in exchange for reductions in size.

Despite efforts to reduce the area required to implement circuits requiring the use of inductors, there remains a need for improvements in reducing the board area and/or volume required for the use of inductors in combination with additional circuit components in microelectronic devices.

### SUMMARY OF THE INVENTION

In carrying out the principles of the present invention, in accordance with preferred embodiments thereof, semiconductor devices and methods for their assembly are described in which inductor elements and additional passive or active circuit components may be combined in novel configurations providing improvements and advantages in conserving overall circuit area.

According to one aspect of the invention, a method for assembling an electronic device includes steps for providing an inductor element encapsulated within a dielectric package. The inductor package includes a plurality of electrical contacts on at least one surface. One or more circuit components are affixed to the package surface and operably coupled to the electrical contacts. The circuit components have a total area not larger than the inductor package surface.

According to another aspect of the invention, a method for manufacturing an electronic device includes steps for encapsulating an inductor element within a dielectric package. The inductor package defines the footprint and height of the completed electronic device. A plurality of conductive traces are provided on one or more inductor package surface for use as electrical contacts. One or more circuit components are affixed to the inductor package surface and operably coupled to the conductive traces for operation in concert with the inductor element.

According to yet another aspect of the invention, in an embodiment thereof, an inductor element is enclosed in a package and a plurality of electrical contacts are disposed on a surface of the package. One or more additional circuit elements are affixed to the package surface and operably coupled to the electrical contacts. The area of the electronic device is bounded by the surface of the inductor package.

According to another aspect of the invention, a method for manufacturing an electronic device includes the steps of providing an inductor element encapsulated within a dielectric package, and providing a plurality of electrical contacts on at least one surface of the package. In another step, one or more circuit components are affixed to the package surface and operably coupled to the electrical contacts. The circuit total area of the circuit components is not larger than the inductor package surface.

According to another aspect of the invention, a method for implementing an inductor circuit includes a step of selecting an inductor element configuration based on performance requirements. The inductor element is packaged in a dielectric package having electrical contacts disposed on one or more surface. In a subsequent step, one or more circuit components are operably coupled to the electrical contacts for operation in association with the inductor element.

According to another aspect of the invention, an embodiment is disclosed in which a method for implementing an inductor circuit includes the steps of providing a leadframe and providing an inductor element on the leadframe. Thereafter, one or more circuit components are operably coupled to the leadframe. Then the leadframe, inductor element, and the one or more circuit components are encased in a dielectric package having a plurality of exposed electrical contacts.

The invention has numerous advantages including but not limited to providing methods and devices offering one or more of the following; improvements in performance, area reduction, volume reduction, and reduced costs. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a simplified cutaway side view of an example of an embodiment of the invention;

FIG. 2 is a simplified top view of the exemplary embodiment of the invention shown in FIG. 1;

FIG. 3 is a simplified top view of an example of another embodiment of the invention;

FIG. 4 is a simplified cutaway side view of an example of an alternative embodiment of the invention;

FIG. 5 is a simplified bottom view of another example of an alternative embodiment of the invention; and

FIGS. 6A through 6D provide a series of cut-away side views of an exemplary method embodying the invention.

References in the detailed description correspond to like references in the various Figures unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general, the invention provides improved integration of one or more inductor element in a device that also includes one or more additional circuit components. As shown and described herein, preferred embodiments of the invention provide integrated microelectronic devices including inductor elements in combination with other circuit components, the combination bounded by the geometry of the inductor package.

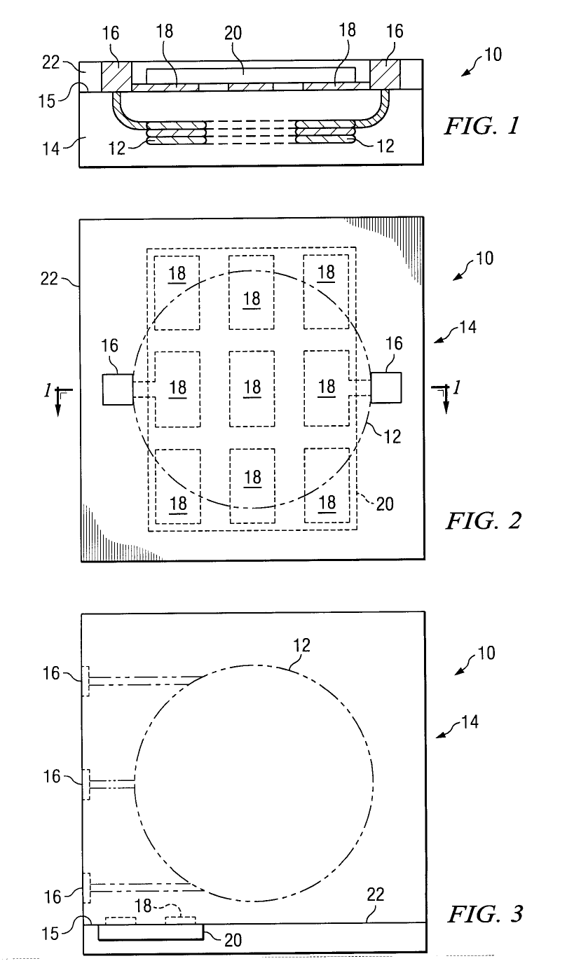

Now referring primarily to FIG. 1, an example of a preferred embodiment of the invention is depicted in a partial cutaway side view. A packaged device 10 of the invention includes an inductor element 12. The inductor element 12 is encapsulated in a dielectric package 14. As shown, a surface 15 of the inductor package 14 has electrical contacts 18 disposed thereupon. The contacts 18 are preferably operably coupled to the inductor element 12 terminals 16 and to one or more additional circuit component 20. It should be appreciated by those skilled in the arts that numerous interconnections between and among the inductor and additional components are possible and that multiple potential uses of the invention may give rise to various operable interconnections not shown in the drawings. The additional circuit component 20 may include passive components, or active integrated circuitry (ICs) or combinations of components. Additional encapsulant 22 may also be used to enclose the additional circuitry 20 and contact-bearing inductor package 14 surface 15 to complete the integrated packaged device 10.

A top view of the device 10 is shown in FIG. 2. It can be seen that the device 10 is bounded by the limits of the inductor package 14. According to the principles of the invention, the inductor element 12 is preferably selected primarily based on the application requirements and not based on area considerations. The additional circuit component 20, such as an IC for example, may be surface-mounted upon the contacts 18 in a manner familiar in the arts. Operable electrical connections may also be provided for coupling to external circuitry. Thus, the inductor element package 14 provides a mounting surface 15 for additional circuit components 20, such as capacitors, resistors, or transistors, or more complex microelectronic circuitry. The additional circuit components are preferably surface-mountable or unpackaged, although small packaged ICs, such as quad flat no-lead package (QFNs) may be used. Typically, the additional circuit components are selected for operation in association with the inductor element. The embodiment of the invention shown in FIGS. 1 and 2 is but one example of a suitable arrangement. The electrical contacts 18 may take various forms within the scope of the invention. For example, traces of conductive material may be laid down on the surface 15 using various patterning and etching techniques know in the arts. The contacts may be as simple a few bond pads permitting passive components to be coupled to the inductor terminals, or may take a more complex form similar to a leadframe on the inductor package surface for the attachment of a sophisticated IC. Additional alternatives for the electrical contacts include arrays of solder balls or pins, either for connection to additional circuit components or for making connections to external devices. Preferably, the configuration used for a particular application will be adapted for achieving desirable overall height and width dimensions. Of course the description of the “top” and “bottom” surfaces herein are in reference to the drawings for the purposes of example. It should be appreciated by those skilled in the arts that in practice the electrical contacts may be provided on any surface of the inductor package, on more than one surface of the inductor package, or on each surface of the inductor package, without departure from the invention. Further connections between and among the electrical contacts, inductor terminals, and additional external terminals for connection outside the device may also be provided as known in the arts according to the requirements of the device application.

An example of an alternative embodiment of the invention is illustrated in FIG. 3. Viewed from above, a device 10 is shown in which an inductor element 12 is encased in encapsulant 14 with inductor terminals 16 incorporated into one surface, in this case on the side of the package 14. Electrical contacts 18 are also provided on a surface 15 of the inductor package 14, in this case on an adjacent side, although the same side or an opposing side may also be used. In the configuration shown in FIG. 3, additional circuit components 20 may be operably coupled to the electrical contacts 18. In some instances it may be desirable to also provide encapsulant 22 over the additional circuit component(s) 20 and exposed inductor package surface 15. It can be seen that, in this example of a particular embodiment of the invention, the device 10 is bounded by the inductor packaging 14, not in footprint, but in height, which may be advantageous in applications where a premium is placed on maintaining a low profile.

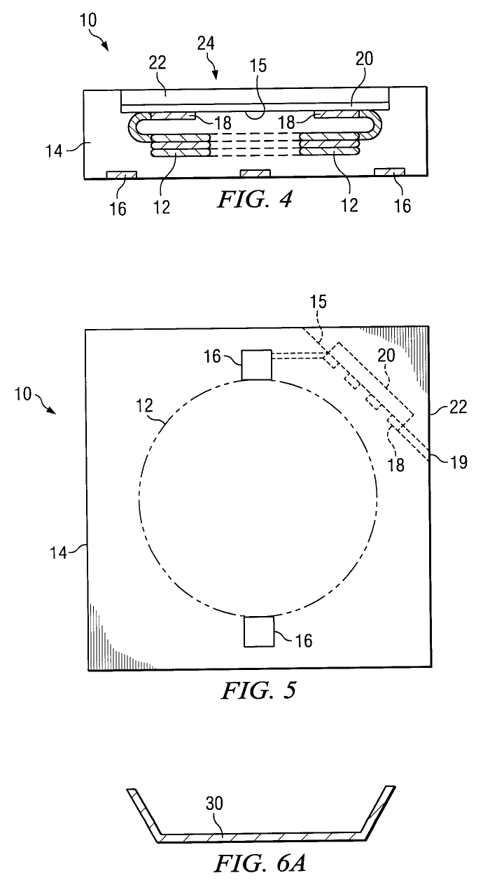

As can be seen in the additional representative embodiment depicted in FIG. 4, according to the invention, the inductor package 14 may be provided with a niche 24 configured to accept the placement of the additional circuit components 20 therein. The exact shape and size of the niche 24 is not crucial to the implementation of the invention so long as the niche 24 provides a volume of space adequate for placement of the additional circuit components 20 for connection with the electrical contacts 18 on the inductor package 14 surface 15. In this example, the inductor terminals 16 are situated on surface of the inductor package 14 opposite the additional circuitry 20. It is shown in this example that the outline of the additional circuit components 20 is wholly contained within the niche 24 of the inductor package 14. The placement of the additional circuit components 20 within the footprint of the inductor package 14 advantageously reduces the total area required for the device 10. In cases where the application may require a relatively large inductor and relatively small IC component, additional componentry, unrelated to the inductor in terms of circuit operation, may also be placed within the niche in order to reduce the overall area used by the application. As shown, the overall height of the device, in addition to the planar footprint, is bounded by the inductor package.

A further example of a device embodying the invention is shown in the bottom view of FIG. 5. In this variation of the invention, a surface 15 of the inductor package 14 is provided with electrical contacts 18 for connection with additional circuit components 20. In this example, the device 10 is bounded, both in height and width, by the inductor package 14. As in other embodiments shown and described, the electrical contacts may be further interconnected in numerous ways as known in the arts. By way of example, connections to an inductor terminal 16 and an external contact 19 for connection outside of the device 10 are shown.

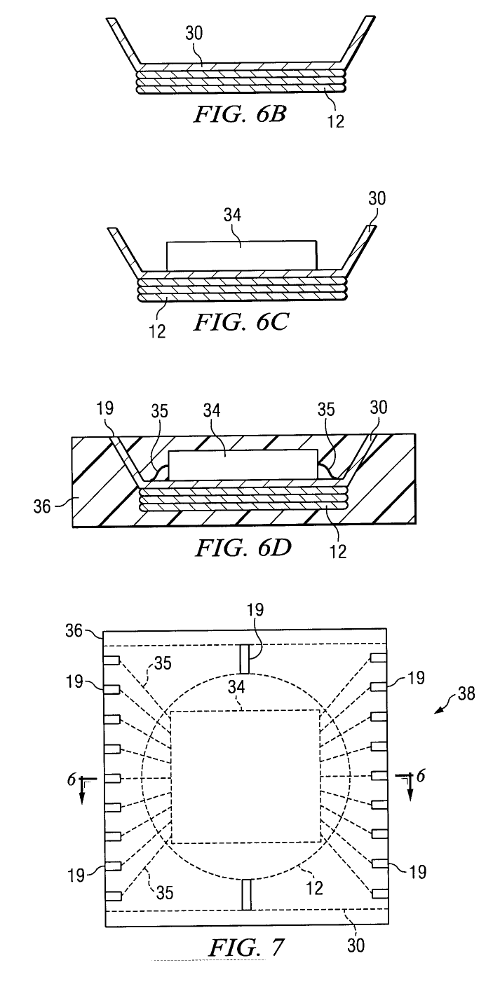

An additional alternative embodiment of the invention is shown in FIGS. 6A through 6D, and FIG. 7. A leadframe 30 is provided, an example of which is shown in FIG. 6A. An inductor winding 32 is formed as shown in FIG. 6B, for example, copper wire may be coupled to the leadframe and powdered iron applied, forming an inductor element 12. Subsequently, referring to FIG. 6C, one or more circuit components, such as an IC 34 for example, is attached to the leadframe 30. The IC 34 is preferably operably coupled to the leadframe 30 by bondwires 35, FIG. 6D. The IC 34, inductor 12, and leadframe 35, are then preferably encapsulated 36 as a single chip assembly 38. Electrical connections within the assembly 36 may be made as necessary to provide operable connections among circuit contacts on the IC 34, leadframe 30, inductor 12, and external contacts 19 for connection to other circuitry (not shown). This is but one example of an implementation of the invention in which an inductor element and additional componentry may first be combined with a leadframe and subsequently overmolded, which may provide particular advantages in some applications.

The invention provides advantages including but not limited to a reduction in the chip area and/or volume required for implementing an inductor and associated components, increased efficiency, and reduced costs. While the invention has been described with reference to certain illustrative embodiments, the methods and systems described are not intended to be construed in a limiting sense. Various modifications and combinations of the illustrative embodiments as well as other advantages and embodiments of the invention will be apparent to persons skilled in the art upon reference to the description and claims.

We claim:

1. A method for manufacturing an electronic device comprising the steps of:
providing an inductor element encapsulated within a dielectric package;
providing a plurality of electrical contacts on at least one surface of the package;
affixing one or more circuit component to the package surface and operably coupling the one or more circuit components to the electrical contacts, the circuit components having a total area not larger than the package surface.

2. A method according to claim 1 whereby the electronic device provides an inductor element component and at least one circuit component within the footprint defined by the inductor element package.

3. A method according to claim 1 whereby the electronic device provides an inductor element and at least one circuit component within the height defined by the inductor element package.

4. A method according to claim 1 wherein the step of providing a plurality of electrical contacts on at least one surface of the package further comprises forming conductive traces in the inductor element package surface.

5. A method according to claim 1 further comprising the step of coupling the inductor element and at least one circuit component for operation in concert.

6. A method for manufacturing an electronic device comprising the steps of:
providing an inductor element encapsulated within a dielectric package, the package having a footprint defining the footprint of the electronic device, the package also having a height defining the height of the electronic device;
forming a plurality of conductive traces on one or more inductor element package surface for use as electrical contacts;
affixing one or more circuit components to the package surface and operably coupling the one or more circuit components to the conductive traces for operation in concert with the inductor element.

7. An electronic device comprising:
an inductor element enclosed in a package;
a plurality of electrical contacts disposed on a surface of the package; and
at least one circuit element affixed to the package surface and operably coupled to the electrical contacts, wherein the area of the electronic device is bounded by the surface of the inductor package.

8. An electronic device according to claim 7 wherein the plurality of electrical contacts further comprise conductive traces bonded to the inductor element package surface.

9. An electronic device according to claim 7 wherein the plurality of electrical contacts further comprise a leadframe.

10. An electronic device inductor according to claim 7 wherein the plurality of electrical contacts further comprise an array of solder balls.

11. An electronic device according to claim 7 wherein the plurality of electrical contacts further comprise an array of pins.

12. An electronic device according to claim 7 wherein the plurality of electrical contacts further comprise inductor terminals.

13. An electronic device according to claim 7 wherein the inductor package further comprises a surface-mountable inductor package.

14. An electronic device according to claim 7 wherein at least one circuit component further comprises a passive component.

15. An electronic device according to claim 7 wherein at least one circuit component further comprises an active component.

16. A method for implementing an inductor circuit, comprising the steps of:
selecting an inductor element configuration based on performance requirements;
packaging the inductor element, the package comprising a dielectric body having electrical contacts disposed on one or more surface of the dielectric package;
operably coupling one or more circuit components to the electrical contacts for operation in association with the inductor element.

17. A method for implementing an inductor circuit, comprising the steps of:
providing a leadframe;
providing an inductor element on the leadframe; subsequently,
operably coupling one or more circuit components to the leadframe; and then,
encapsulating the leadframe, inductor element, and the one or more circuit components in a dielectric package having a plurality of electrical contacts disposed on one or more surface.
